(19) United States
(12) Patent Application Publication
(10) Pub. No.: US 2026/0334056 A1
(43) Pub. Date: Oct. 22, 2026

(54) ELECTRONIC PANEL

(71) Applicant: Samsung Display Co., LTD., Yongin-si (KR)

(72) Inventor: SUNGSIK YUN, Yongin-si (KR)

(21) Appl. No.: 19/434,337

(22) Filed: Dec. 29, 2025

(30) Foreign Application Priority Data
Apr. 21, 2025 (KR) 10-2025-0051734

(51) Int. Cl. H10K 59/80; H10K 59/122; H10K 59/88

(52) U.S. Cl. CPC H10K 59/873; H10K 59/122; H10K 59/88

(57) ABSTRACT

An electronic panel includes a display panel with a display area including a margin region and a dam region, and an upper film on the display panel. The display panel includes a base layer, insulating layers on the base layer, pixels on the base layer, an encapsulation layer covering the pixels and including a first encapsulation inorganic layer, a second encapsulation inorganic layer, and an encapsulation organic layer between the first and second encapsulation inorganic layers, dam patterns on the dam region, and a dummy dam pattern along a boundary of the margin region. The dummy dam pattern includes an inorganic pattern, a first organic pattern on the inorganic pattern, a second organic pattern on the first organic pattern, a conductive pattern between the first and second organic patterns and protruding from the first and second organic patterns, and a third organic pattern on the second organic pattern.

This application claims priority to Korean Patent Application No. 10-2025-0051734, filed on Apr. 21, 2025, and all the benefits accruing therefrom under 35 U.S.C. §119, the content of which in its entirety is herein incorporated by reference.

### BACKGROUND

### 1. FIELD

The disclosure relates to an electronic device. More particularly, the disclosure relates to an electronic device in which infiltration of moisture/oxygen is improved in a bending region.

### 2. DESCRIPTION OF THE RELATED ART

A variety of display devices used for multimedia apparatuses such as televisions, mobile phones, tablet computers, navigation systems, and game consoles continues to be developed. A display panel in which a housing receives a bending region to reduce a dead space of the display device continues to be researched. The infiltration of moisture/oxygen may occur due to organic layers disposed on the bending region.

### SUMMARY

An embodiment of the disclosure provides an electronic device in which infiltration of moisture/oxygen is improved in a bending region.

According to an embodiment of the disclosure, an electronic panel may include: a display panel with a display area including a margin region and a dam region that surrounds the margin region; and an upper film on the display panel. The display panel may include: a base layer; a plurality of insulating layers on the base layer; a plurality of pixels on the base layer that overlaps the display area; an encapsulation layer that covers the plurality of pixels and includes a first encapsulation inorganic layer, a second encapsulation inorganic layer, and an encapsulation organic layer between the first encapsulation inorganic layer and the second encapsulation inorganic layer; a plurality of dam patterns on the dam region; and a dummy dam pattern along a boundary of the margin region. The dummy dam pattern may include: an inorganic pattern; a first organic pattern on the inorganic pattern; a second organic pattern on the first organic pattern; a conductive pattern between the first and second organic patterns and protruding from the first and second organic patterns; and a third organic pattern on the second organic pattern.

In an embodiment, within the margin region, the dummy dam pattern may define a boundary of the encapsulation organic layer. The encapsulation organic layer may be absent between the dummy dam pattern and an outermost dam pattern of the plurality of dam patterns. The outermost dam pattern may be closest (most adjacent) to the margin region among the plurality of dam patterns.

In an embodiment, each of the plurality of pixels may include: a first electrode; a second electrode on the first electrode; and an emission layer between the first electrode and the second electrode. The electronic panel may further include an emission pattern layer on the margin region, the emission pattern layer covering the dummy dam pattern.

In an embodiment, the emission pattern layer may include a material the same as a material of the emission layer.

In an embodiment, the first encapsulation inorganic layer may cover the plurality of dam patterns on the dam region and the emission pattern layer on the margin region.

In an embodiment, the plurality of insulating layers may include: a plurality of inorganic insulating layers each including an inorganic material; a first organic insulating layer on the inorganic insulating layers; and a second organic insulating layer on the first organic insulating layer.

In an embodiment, none of the first organic insulating layer and the second organic insulating layer may be disposed between the dummy dam pattern and a boundary between the dam region and the margin region.

In an embodiment, the first encapsulation inorganic layer and the second encapsulation inorganic layer may contact each other from one of the plurality of dam patterns to the dummy dam pattern.

In an embodiment, each of the plurality of dam patterns may include: a first dielectric pattern; a first pattern on the first dielectric pattern; a second pattern on the first pattern; and a second dielectric pattern on the first dielectric pattern. The second pattern may protrude between the first and second dielectric patterns.

In an embodiment, the first organic pattern and the first dielectric pattern may include a material the same as a material of the first organic insulating layer. The second organic pattern and the second dielectric pattern may include a

material the same as a material of the second organic insulating layer.

In an embodiment, the display panel may further include: a pixel definition layer on the second organic insulating layer and including a plurality of openings each of which exposes at least a portion of a first electrode included in each of the plurality of pixels; and a spacer on the pixel definition layer.

In an embodiment, the third organic pattern may include a material the same as a material of at least one selected from the pixel definition layer and the spacer.

In an embodiment, the plurality of pixels may include a transistor and an emission element connected to the transistor.

In an embodiment, the electronic panel may further include a plurality of dummy pixels that overlap the margin region and are surrounded by the dummy dam pattern.

In an embodiment, each of the plurality of dummy pixels may include: a dummy transistor that has a structure the same as a structure of the transistor; and a dummy emission element that has a structure the same as a structure of the emission element. The dummy transistor may be disconnected to the dummy emission element.

In an embodiment, the electronic panel may further include a protruding pattern between organic layers of the insulating layers on the margin region. The organic layers may face the dummy dam pattern. The protruding pattern may protrude in a direction toward the dummy dam pattern.

In an embodiment, the electronic panel may further include a step compensation layer on the second encapsulation inorganic layer. The step

compensation layer may overlap at least one of the plurality of dam patterns and include an organic material. The step compensation layer may have a ring shape.

In an embodiment, the electronic panel may further include: a planarization layer on an entirety of the display area, the planarization layer covering the step compensation layer; and an adhesion layer between the planarization layer and the upper film.

In an embodiment, the adhesion layer and the upper film may be separable from the planarization layer.

In an embodiment, when viewed in plan, an arrangement of the plurality of dam patterns may be different from an arrangement of the dummy dam pattern.

### BRIEF DESCRIPTION OF DRAWINGS

The above and other embodiments, advantages and features of this disclosure will become more apparent by describing in further detail embodiments thereof with reference to the accompanying drawings.

FIG. 1A illustrates a block diagram showing an embodiment of an electronic device.

FIG. 1B illustrates simplified diagrams showing embodiments of electronic devices.

FIG. 1C illustrates a diagram showing an embodiment of the interior of a vehicle equipped with an electronic device.

FIG. 2 illustrates a cross-sectional view showing an embodiment of an electronic device.

FIG. 3 illustrates a plan view showing an embodiment of an electronic device.

FIG. 4 illustrates a cross-sectional view taken along line I-I’ of FIG. 3.

FIG. 5 illustrates a cross-sectional view taken along line II-II’ of FIG. 3.

FIG. 6 illustrates a plan view showing an embodiment of an electronic panel.

FIG. 7 illustrates an enlarged plan view partially showing an embodiment of an electronic panel.

FIG. 8 illustrates a cross-sectional view taken along line III-III” of FIG. 7.

FIG. 9 illustrates a cross-sectional view taken along line IV-IV’ of FIG. 7.

FIG. 10 illustrates a cross-sectional view showing an embodiment of a margin region of an electronic panel.

FIG. 11A illustrates a plan view showing an embodiment of an electronic panel.

FIG. 11B illustrates a cross-sectional view taken along line V-V’ of FIG. 11A.

FIG. 12 illustrates a plan view showing an embodiment of an electronic panel.

FIG. 13 illustrates a plan view showing an embodiment of an electronic panel.

FIG. 14 illustrates a plan view showing an embodiment of an electronic panel.

### DETAILED DESCRIPTION

In this description, when a certain component (or region, layer, portion, etc.) is referred to as being “on”, “connected to”, or “coupled to” other component(s), the certain component may be directly on, directly connected to, or directly coupled to the other component(s) or at least one intervening component may be therebetween.

Like numerals indicate like components. Moreover, in the drawings, thicknesses, ratios, and dimensions of components are exaggerated for effectively explaining the technical contents. The term “and/or” includes one or more combinations defined by associated components.

It will be understood that, although the terms first, second, etc. may be used herein to describe various components, these components should not be limited by these terms. These terms are only used to distinguish one component from another component. For example, a first component could be termed a second component, and vice versa without departing from the scope of the present invention. Unless the context clearly indicates otherwise, the singular forms are intended to include the plural forms as well.

In addition, the terms “beneath”, “lower”, “above”, “upper”, and the like are used herein to describe one component’s relationship to other component(s) illustrated in the drawings. The relative terms are intended to encompass different orientations in addition to the orientation depicted in the drawings.

It should be understood that the terms “comprise”, “include”, “have” , and the like are used to specify the presence of stated features, integers, steps, operations, components, elements, or combinations thereof, but do not preclude the presence or addition of one or more other features, integers, steps, operations, components, elements, or combinations thereof.

Unless otherwise defined, all terms used herein including technical and scientific terms have the same meaning generally understood by one of ordinary skilled in the art. Also, terms as defined in dictionaries generally used should be understood as having meaning identical or meaning contextually defined in the art and should not be understood as ideally or excessively formal meaning unless definitely defined herein.

The following will now describe some embodiments of the disclosure in conjunction with the accompanying drawings.

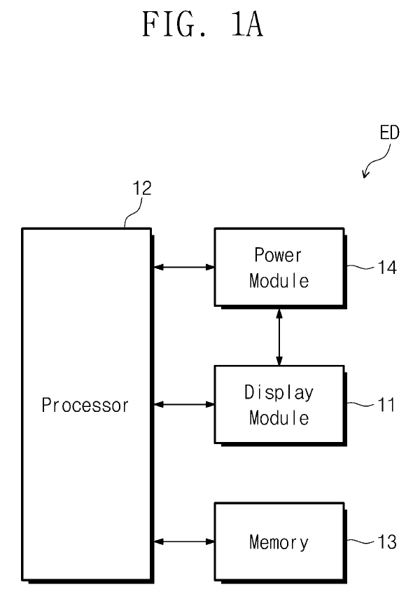

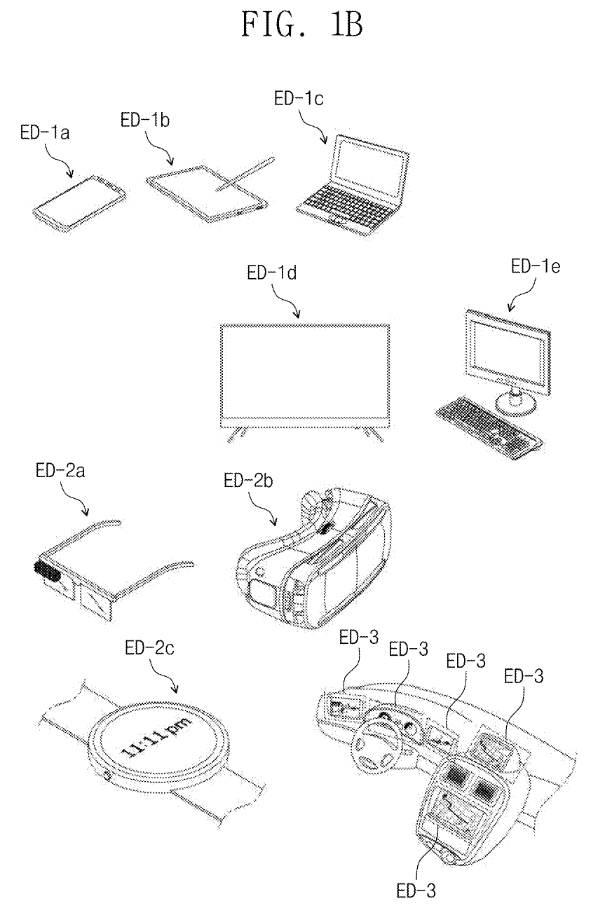

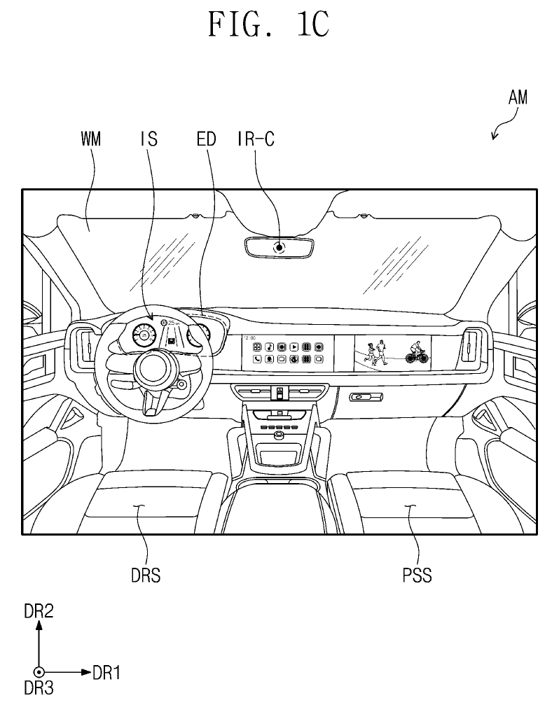

FIG. 1A illustrates a block diagram showing an embodiment of an electronic device. FIG. 1B illustrates simplified diagrams showing embodiments of an electronic device.

Referring to FIG. 1A, an electronic device ED in an embodiment may include a display module 11, a processor 12, a memory 13, and a power module 14.

The processor 12 may include at least one selected from a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, the display module 11 may receive one or more of image data signals and input control signals, and may process the received one or more signals to output image information through a display screen.

The power module 14 may include a power supply module such as a power adaptor or a battery device, and also include a power conversion module that converts power supplied by the power supply module to generate power desired for the operation of the electronic device ED.

At least one of components in the electronic device ED may be included in a display device in an embodiment described below. In addition, at least one of individual modules functionally included in one module may be included in a display device, and at least another of individual modules may be provided separately from a display device. In an embodiment, the display module 11 may be included in a display device, and the processor 12, the memory 13, and the power module 14 may be provided in the form of other apparatuses within the electronic device ED other than the display device, for example.

Referring to FIG. 1B, various electronic devices to each of which a display device in an embodiment is applied may include an image display electronic device such as a smart phone ED-1a, a tablet personal computer ED-1b, a laptop computer ED-1c, a television set ED-1d, and a desk monitor ED-1e, a wearable electronic device including a display module such as smart glasses ED-2a, a head-mounted display ED-2b, and a smart watch ED-2c, and a vehicle electronic device ED-3 including a display module such as an instrument cluster, a center fascia, a center information display (“CID”) arranged on a vehicle dashboard, and a room mirror display.

The electronic device in an embodiment may include a display device described below, and further include a module or device having additional functions in addition to the display device. FIG. 1C depicts, as one of the embodiments, an embodiment of the electronic device ED, which is included in an automobile AM, corresponding to the vehicle electronic device ED-3 discussed above.

The electronic device ED in an embodiment may be disposed to reside within the automobile AM and to provide various information to a user in a driver seat DRS or a passenger seat PSS. The electronic device ED may display an image on a display surface IS. The display surface IS that displays the image may correspond to a front surface of the electronic device ED. The image may include not only a dynamic image but also a static image.

The display surface IS may be parallel to each of a first directional axis DR1 and a second directional axis DR2. The embodiment, however, is not limited thereto, and the display surface IS of the electronic device ED may include either a curved surface that reflects vehicle internal design or a flat surface that is inclined to a plane defined by the first directional axis DR1 and the second directional axis DR2. A third directional axis DR3 may indicate a normal direction of the display surface IS or a thickness direction of the electronic device ED. In an embodiment, a rear view mirror may include light emitters (e.g., infrared (“IR”) or near IR emitters) IR-C.

FIG. 1C and following drawings depict the first directional axis DR1, the second directional axis DR2, and the third directional axis DR3, and directions indicated by the first, second, and third directional axes DR1, DR2, and DR3 are relative concepts and may thus be changed to other directions. In addition, the directions indicated by the first, second, and third directional axes DR1, DR2, and DR3 may be described as first, second, and third directions, and may be denoted by the same reference numerals. In this description, the first directional axis (also referred to as a first direction) DR1 and the second directional axis (also referred to as a second direction) DR2 may be orthogonal to each other, and the third directional axis (also referred to as a third direction) DR3 may be normal to a plane defined by the first direction DR1 and the second direction DR2.

In this description, the first direction DR1 may be also referred to as a left-right direction, the second direction DR2 may be also referred to as a top-bottom direction, and the third direction DR3 may be also referred to as a thickness direction.

A front surface (or top surface) and a rear surface (or bottom surface) of each component included in the electronic device ED may be opposite to each other in the third direction DR3, and a normal direction to each of the front and rear surfaces may be parallel to the third direction DR3. An interval between the front and rear surfaces defined along the third direction DR3 may correspond to a thickness of the component.

In this description, the expression of “when viewed in plan” or “in a plan view” may be defined to represent a state when viewed in the third direction DR3. In this description, the expression of “when viewed in cross-section” or “in a cross-section” may be defined to represent a state when viewed in the first direction DR1 or the second direction DR2.

The display surface IS of the electronic device ED may have various shapes depending on design of the automobile AM. The electronic device ED disposed opposite to the driver seat DRS may include components relevant not only to driving requirement information such as vehicle condition information, vehicle internal operation information, and navigation information, but also to a vehicle control system that operates during an autonomous driving.

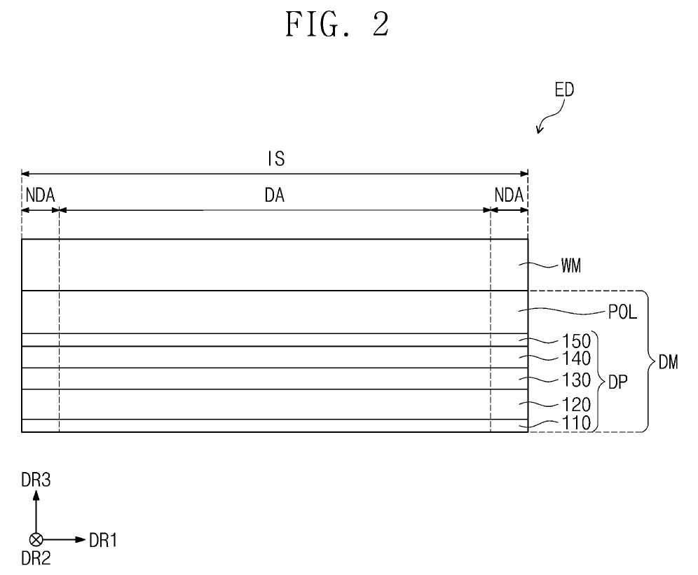

FIG. 2 illustrates a cross-sectional view showing an embodiment of an electronic device. The electronic device ED may include a display module DM and a window module WM. The display module DM may include a display panel DP and an optical control member POL.

The window module WM may be disposed on the optical control member POL. A front surface of the window module WM may define the display surface IS of the electronic device ED. The window module WM may have a shape corresponding to that of the display module DM.

The window module WM may include a substrate or film including glass or a polymer material. In addition, the window module WM may further include a functional layer, such as a protective film disposed on a base substrate or film. The window module WM and the optical control member POL may be combined through an adhesion layer that is additional disposed. The adhesion layer may be an optically clear adhesive (“OCA”). In an embodiment, the window module WM may be omitted.

The display panel DP may include a base layer 110, a circuit element layer 120, a display layer 130, an encapsulation layer 140, and a planarization layer 150. The display panel DP may be a component that substantially produces an image.

The display panel DP included in the electronic device ED in an embodiment may be an organic light-emitting display panel, an inorganic light-emitting display panel, an organic-inorganic light-emitting display panel, a quantum-dot display panel, a micro-light-emitting diode (“micro-LED”) display panel, a nano-LED display panel, or the like. The illustrated embodiment describes a case where the display panel DP is an organic light-emitting display panel, but the embodiment of the display panel DP is not limited thereto.

The base layer 110 may be a member that provides a base surface on which the circuit element layer 120 and the display layer 130 are disposed. The base layer 110 may be rigid or flexible. The base layer 110 may be a glass substrate, a metal substrate, or a polymer substrate. The embodiment, however, is not limited thereto, and the base layer 110 may be an inorganic layer, an organic layer, or a composite material layer.

The base layer 110 may have not only a single-layered structure or a multi-layered structure. In an embodiment, the base layer 110 may have a tri-layered structure of a polymer resin layer, an adhesion layer, and a polymer resin layer, for example. In an embodiment, the polymer resin layer may include a polyimide-based resin, for example. In an alternative embodiment, the polymer resin layer may include at least one selected from an acrylate-based resin, a vinyl-based resin, an epoxy-based resin, a urethane-based resin, a cellulose-based resin, a siloxane-based resin, and a perylene-based resin. In this description, the language “X-based resin” means a resin that includes a functional group of X.

The circuit element layer 120 may be disposed on the base layer 110., The circuit element layer 120 may include insulating layers (including or consisting of an inorganic material or an organic material), a semiconductor pattern, a conductive pattern, a signal line, and so forth. The circuit element layer 120 may include a plurality of transistors including or consisting of a semiconductor pattern, a conductive pattern, a signal line, and so forth. Each of the transistors may include a control electrode, an input electrode, and an output electrode. In an embodiment, the circuit element layer 120 may include a switching transistor and a driving transistor to drive emission elements, for example.

The display layer 130 may be disposed on the circuit element layer 120. The display layer 130 may include an emission element contained in each of pixels. The light generated from the display layer 130 may pass through the optical control member POL on the display layer 130 and travel toward the display surface IS of the electronic device ED.

The encapsulation layer 140 may be disposed on the display layer 130, thereby covering the emission elements. The encapsulation layer 140 may be disposed on the display layer 130. The encapsulation layer 140 may protect the display layer 130 against foreign substances such as moisture, oxygen, and dust particles. Therefore, the encapsulation layer 140 may increase reliability of the electronic device ED.

The encapsulation layer 140 may be disposed on the display layer 130. The encapsulation layer 140 may function to prevent the display layer 130 from attach of foreign substances such as moisture/oxygen. The encapsulation layer 140 may have a structure in which at least one organic layer and at least one inorganic layer are alternately stacked.

The planarization layer 150 may be disposed on the encapsulation layer 140. The planarization layer 150 may compensate a step difference formed by components that are disposed below the planarization layer 150, and may provide a planarized surface to components which will be disposed on the planarization layer 150. The planarization layer 150 may include an organic material.

The optical control member POL may be disposed on the planarization layer 150. The optical control member POL may include at least one selected from a retarder, a polarizer, a polarizing film, and a polarizing filter. In an alternative embodiment, the optical control member POL may include a plurality of color filters disposed in a predetermined arrangement, and also include a black matrix next (adjacent) to the color filters.

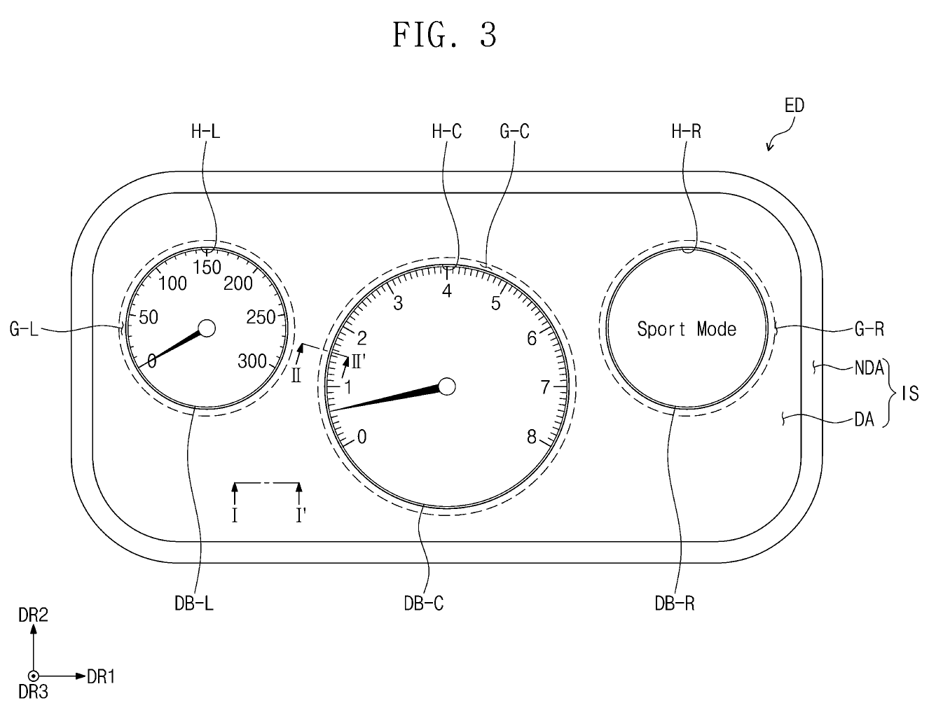

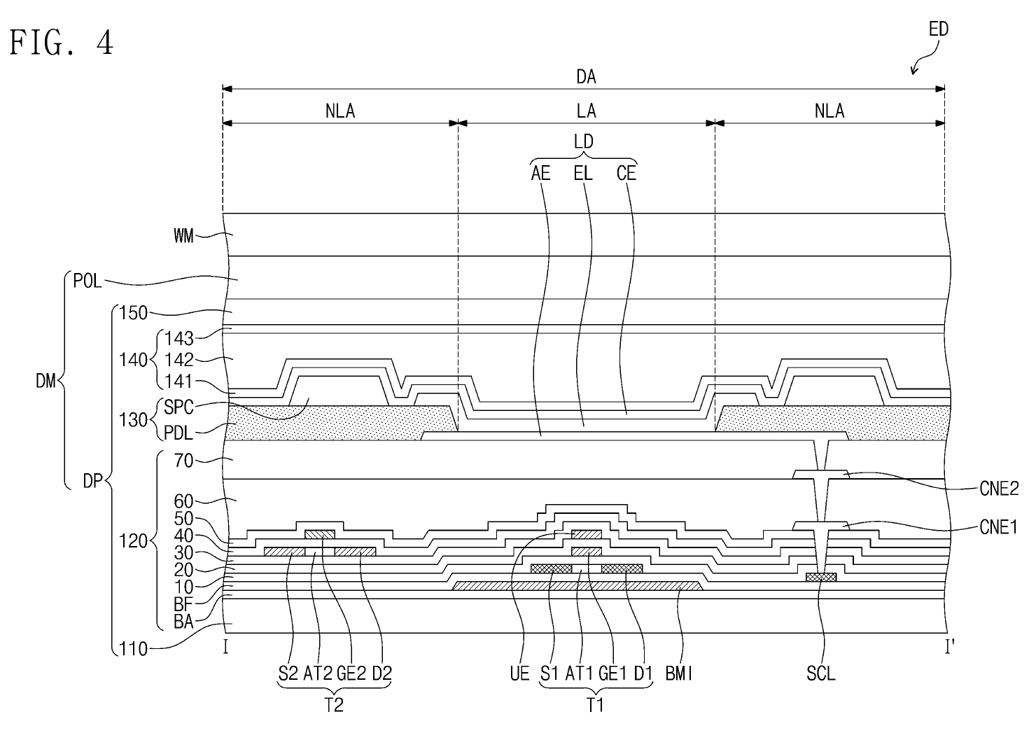

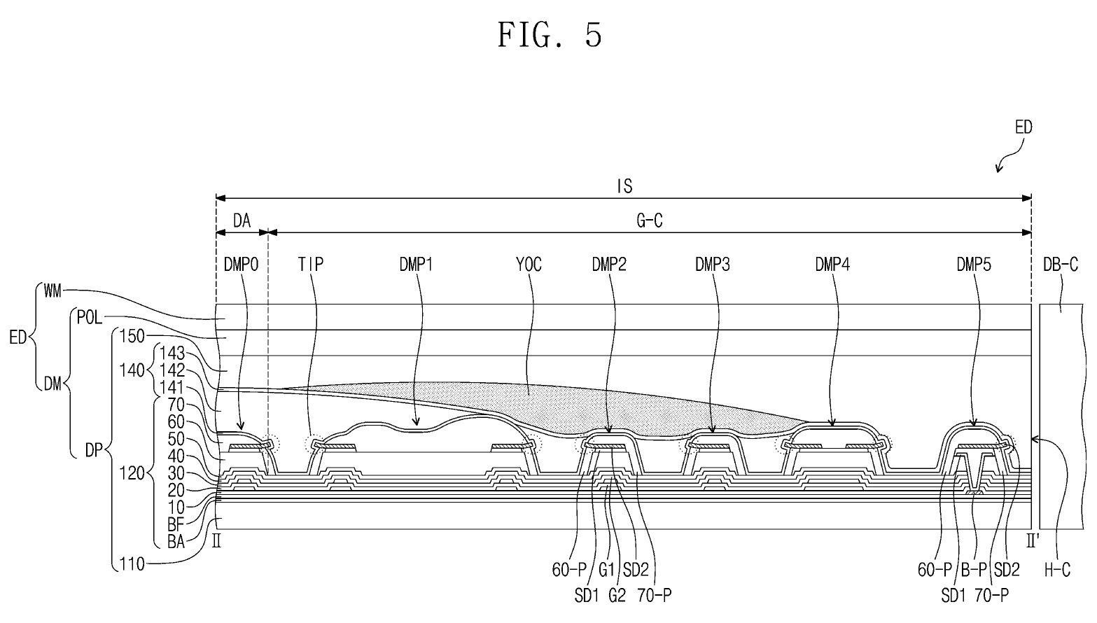

FIG. 3 illustrates a plan view showing an embodiment of an electronic device. FIG. 4 illustrates a cross-sectional view taken along line I-I’ of FIG. 3. FIG. 5 illustrates a cross-sectional view taken along line II-II’ of FIG. 3.

Referring to FIG. 3, when viewed in plan, an electronic device ED in an embodiment may include a display surface IS. The display surface IS may include a display area DA and a non-display area NDA. The non-display area NDA may be disposed outside at least one side of the display area DA. In an embodiment, the display area DA may be defined to refer to a zone where pixels are disposed and images are provided. The non-display area NDA may be a zone that surrounds the display area DA. The disclosure, however, is not limited thereto, and the non-display area NDA may not be provided in an embodiment of the disclosure.

According to the disclosure, holes H-C, H-R, and H-L may thoroughly penetrate the electronic device ED. Instrument clusters DB-C, DB-R, and DB-L interoperating with the automobile (refer to AM of FIG. 1C) may be disposed in lower portions of the holes H-C, H-R, and H-L. The instrument clusters DB-C, DB-R, and DB-L may indicate navigation information, vehicle states such as speeds, revolutions per minute (“RPMs”), and refueling amounts, and external images of traffic lanes next (adjacent) to the automobile AM, and the functions of the instrument clusters DB-C, DB-R, and DB-L are not limited to a particular embodiment as long as they are built in existing vehicles.

The holes H-C, H-R, and H-L may be defined within the display area DA. There may thus be desired a structure that prevents passage of moisture/oxygen introduced through the holes H-C, H-R, and H-L into the display area DA. FIG. 3 depicts, as one of the embodiments, dot lines that represent dam regions G-C, G-R, and G-L where dam patterns (discussed below) are disposed to prevent passage of moisture/oxygen introduced from the holes H-C, H-R, and H-L into the display area DA.

Each of the dam regions G-C, G-R, and G-L may surround a corresponding one of the holes H-C, H-R, and H-L. Therefore, the dam regions G-C, G-R, and G-L may have closed-line shapes that respectively surround the holes H-C, H-R, and H-L. The dam regions G-C, G-R, and G-L may be surrounded by the display area DA. Thus, when viewed in plan, the dam regions G-C, G-R, and G-L may be disposed between the display area DA and the holes H-C, H-R, and H-L.

In addition, there may be desired a structure that prevents delamination of insulating layers disposed on dummy portions disposed within the holes H-C, H-R, and H-L before their formation.

An embodiment, with respect to any one hole H-C of the holes H-C, H-R, and H-L and the dam region G-C that surrounds the hole H-C, and its related embodiments may be commonly applied to other holes H-R and H-L and the dam regions G-R and G-L.

FIG. 4 illustrates a cross-sectional view showing one pixel in the display area DA of the electronic device ED depicted in FIG. 3.

The electronic device ED may include a display module DM and a window module WM. The display module DM may include a display panel DP and an optical control member POL. The display panel DP may include a base layer 110, a circuit element layer 120, a display layer 130, an encapsulation layer 140, and a planarization layer 150. The display panel DP may be a component that substantially produces an image.

The base layer 110 may correspond to that discussed above. The base layer 110 in an embodiment may have a structure in which organic layers and inorganic layers are stacked. In an embodiment, the base layer 110 may include a first organic layer, a first inorganic layer disposed on the first organic layer, a second organic layer disposed on the first inorganic layer, and a second inorganic layer disposed on the second organic layer, for example.

The first and second organic layers may each include an organic material. In an embodiment, the first and second organic layers may each include at least one selected from polyimide (“PI”), polyethylene naphthalate (“PEN”), polyethylene terephthalate (“PET”), polyarylate (“PAR”), polycarbonate (“PC”), polyetherimide (“PEI”), and polyethersulfone (“PES”), for example.

The first and second inorganic layers may each include an inorganic material. In an embodiment, the first and second inorganic layers may each include at least one selected from silicon oxide, silicon oxynitride, aluminum oxide, titanium oxide, silicon nitride, zirconium oxide, hafnium oxide, and amorphous silicon, for example.

A barrier layer BA may be disposed on the base layer 110. The base layer 110 may prevent introduction of external foreign substances. The base layer 110 may include at least one inorganic layer. The base layer 110 may prevent introduction of external foreign substances.

When the base layer 110 includes or consists of four layers discussed above, the second inorganic layer disposed at the top position may correspond to the barrier layer BA, but the disclosure is not limited to a particular embodiment.

A light-shield pattern BMI may overlap a first semiconductor pattern included in a first transistor T1. In an embodiment, the light-shield pattern BMI may also overlap a second semiconductor pattern included in a second transistor T2. The light-shield pattern BMI may include metal. In an embodiment, the light-shield pattern BMI may include molybdenum (Mo), for example.

The light-shield pattern BMI may prevent external light from reaching the first and second transistors T1 and T2. In an embodiment of the disclosure, the light-shield pattern BMI may be a floating electrode that is isolated from other electrodes or wiring lines.

A buffer layer BF may cover the light-shield pattern BMI and reside on the barrier layer BA. The buffer layer BF may prevent metal elements or impurities from diffusing from the base layer 110 toward the overlying first and second semiconductor patterns.

A first insulating layer 10 may be disposed on the buffer layer BF. In an embodiment, first, second, third, fourth, and fifth insulating layers 10, 20, 30, 40, and 50 may each include a single inorganic layer or multiple inorganic layers. In an embodiment, each of the first to fifth insulating layers 10 to 50 may be provided in the form of either a single layer including one of silicon nitride, silicon oxynitride, silicon oxide, titanium oxide, zirconium oxide, hafnium oxide, and aluminum oxide, or a multiple layer including at least two selected from the materials mentioned above, for example.

The first semiconductor pattern of the first transistor T1 may be disposed on the first insulating layer 10. FIG. 4 depicts a portion of the first semiconductor pattern, but the first semiconductor pattern may further be disposed on other section of the pixel. The first semiconductor pattern may have different electrical properties depending on whether the first semiconductor pattern is doped or not. The first semiconductor pattern may include a doped region and a non-doped region. The doped region may be doped with n-type or p-type impurities. A p-type transistor may include a doped region implanted with p-type impurities.

The first semiconductor pattern may be formed into a source S1, an active AT1, and a drain D1 of the first transistor T1. The source S1 and the drain D1 of the first transistor T1 may be formed spaced apart from each other across the active AT1 of the first transistor T1.

A connection signal line SCL may be disposed on the first insulating layer 10. The connection signal line SCL may be connected to one of a plurality of transistors included in the pixel.

The second insulating layer 20 may cover the first semiconductor pattern and the connection signal line SCL, while being disposed on the first insulating layer 10. In the illustrated embodiment, the second insulating layer 20 may be provided as an inorganic layer.

A gate GE1 of the first transistor T1 may be disposed on the second insulating layer 20. The gate GE1 may be a portion of a metal pattern. The gate GE1 of the first transistor T1 may overlap the active AT1 of the first transistor T1. The gate GE1 of the first transistor T1 may act as a mask in a process where the first semiconductor pattern is doped.

The second insulating layer 20 may be provided thereon with the third insulating layer 30 that covers the gate GE1. In the illustrated embodiment, the third insulating layer 30 may be provided as an inorganic layer.

An upper electrode UE may be disposed on the third insulating layer 30. The upper electrode UE may overlap the gate GE1. The upper electrode UE may be a portion of either a metal pattern or a doped semiconductor pattern. A portion of the gate GE1 and the upper electrode UE that overlaps the portion of the gate GE1 may define a capacitor included in the pixel. In an embodiment of the disclosure, the upper electrode UE may be omitted.

The second semiconductor pattern of the second transistor T2 may be disposed on the third insulating layer 30. The second semiconductor pattern may include an oxide semiconductor including metal oxide. The oxide semiconductor may include a crystalline or amorphous oxide semiconductor.

In an embodiment, the oxide semiconductor may include an oxide of metal, such as zinc (Zn), indium (In), gallium (Ga), tin (Sn), and titanium (Ti), or may include a combination of metal, such as zinc (Zn), indium (In), gallium (Ga), tin (Sn), and titanium (Ti), and oxide thereof, for example. The oxide semiconductor may include indium-tin oxide (“ITO”), indium-gallium-zinc oxide (“IGZO”), zinc oxide (ZnO), indium-zinc oxide (“IZO”), zinc-indium oxide (“ZIO”), indium oxide (InO), titanium oxide (TiO), indium-zinc-tin oxide (“IZTO”), or zinc-tin oxide (“ZTO”).

The second semiconductor pattern may be formed into a source S2, an active AT2, and a drain D2 of the second transistor T2. The source S2 and the drain D2 may each include metal reduced from a metal oxide semiconductor. The source S2 and the drain D2 may each include a metal layer having a predetermined thickness from a top surface of the second semiconductor pattern and including the reduced metal.

The third insulating layer 30 may be provided thereon with the fourth insulating layer 40 that covers the second semiconductor pattern and the upper electrode UE. In the illustrated embodiment, the fourth insulating layer 40 may be provided as an inorganic layer.

A gate GE2 of the second transistor T2 may be disposed on the fourth insulating layer 40. The gate GE2 may be a portion of a metal pattern. The gate GE2 of the second transistor T2 may overlap the active AT2 of the second transistor T2.

The fourth insulating layer 40 may be provided thereon with the fifth insulating layer 50 that covers the gate GE2. In the illustrated embodiment, the fifth insulating layer 50 may be provided as an inorganic layer.

A first connection electrode CNE1 may be disposed on the fifth insulating layer 50. The first connection electrode CNE1 may be coupled to the connection signal line SCL through a first contact hole that penetrates the first to fifth insulating layers 10 to 50.

At least one organic insulating layer may further be disposed on the fifth insulating layer 50. As in the illustrated embodiment, a sixth insulating layer 60 and a seventh insulating layer 70 may be disposed on the fifth insulating layer 50. The sixth insulating layer 60 and the seventh insulating layer 70 may each be an organic layer and have a single-layered or multi-layered structure. The sixth insulating layer 60 and the seventh insulating layer 70 may each be a single-layered polyimide-based resin layer.

The disclosure, however, is not limited thereto, and the sixth insulating layer 60 and the seventh insulating layer 70 may each include at least one selected from acryl-based resin, methacryl-based resin, polyisoprene, vinyl-based resin, epoxy-based resin, urethane-based resin, cellulose-based resin, siloxane-based resin, polyamide-based resin, and perylene-based resin.

A second connection electrode CNE2 may be disposed on the sixth insulating layer 60. The second connection electrode CNE2 may be connected to the first connection electrode CNE1 through a second contact hole that penetrates the sixth insulating layer 60.

An emission element LD may be disposed on the seventh insulating layer 70. A first electrode AE of the emission element LD may be disposed on the seventh insulating layer 70. A pixel definition layer PDL may be disposed on the seventh insulating layer 70. The pixel definition layer PDL may have a display opening that exposes at least a portion of the first electrode AE. In the illustrated embodiment, the pixel definition layer PDL may include a light absorbing material. In an embodiment, the pixel definition layer PDL may have a black color, for example.

In an embodiment, the display panel DP may have an emission area LA that corresponds to the display opening. In the display area DA, a region that overlaps the pixel definition layer PDL may be defined as a non-emission area NLA, and the non-emission area NLA may surround a plurality of emission areas LA.

A spacer SPC may be disposed on the pixel definition layer PDL. The spacer SPC may prevent the pixel definition layer PDL of a black component from being externally recognized, and a groove may be defined to rigidly place a supporter for supporting a mask in a process where a deposition process is employed to form an emission layer EL which will be discussed below. The groove may penetrate at least a portion of the spacer SPC. The spacer SPC may be an organic layer including polyimide. The spacer SPC may have a spacer opening that exposes the first electrode AE and overlaps the display opening.

An emission layer EL may be disposed within the display opening and on the first electrode AE. In an embodiment of the disclosure, a hole control layer may be disposed between the first electrode AE and the emission layer EL. The hole control layer may include a hole transport layer and further include a hole injection layer. An electron control layer may be disposed between the emission layer EL and a second electrode CE which will be discussed below. The electron control layer may include an electron transport layer and further include an electron injection layer.

A second electrode CE may be disposed on the emission layer EL. The electron control layer may be disposed between the emission layer EL and the second electrode CE. In an embodiment, the second electrode CE may be disposed on the electron control layer, for example. The electron control layer, the hole control layer, and the second electrode CE may be disposed in common on a plurality of pixels.

The encapsulation layer 140 may cover the emission element LD. The encapsulation layer 140 may include a first encapsulation inorganic layer 141, an encapsulation organic layer 142, and a second encapsulation inorganic layer 143 that are sequentially stacked. The layers that constitute the encapsulation layer 140, however, are not limited thereto. The encapsulation inorganic layers 141 and 143 may each include a silicon nitride layer, a silicon oxynitride layer, a silicon oxide layer, a titanium oxide layer, or an aluminum oxide layer. Each of the encapsulation inorganic layers 141 and 143 may have a multi-layered structure. The encapsulation organic layer 142 may include an acryl-based organic layer, but the disclosure is not limited thereto.

In an embodiment, there may further be included an input sensor directly disposed on the encapsulation layer 140. The input sensor may include at least one conductive layer (or at least one sensor conductive layer) including conductive patterns and at least one sensing insulating layer (or at least one sensor insulating layer). The input sensor may use a capacitive method to detect an external input.

The optical control member POL may be disposed on the encapsulation layer 140. The optical control member POL may be coupled to the encapsulation layer 140 through an adhesion layer that is separately provided or may be directly disposed on the encapsulation layer 140 without any separate adhesion layer.

The window module WM may be disposed on the optical control member POL. The window module WM may be coupled to the optical control member POL through an adhesion layer that is separately provided. The adhesion layers mentioned above may include at least one selected from an optically clear adhesive (“OCA”), an optically clear adhesive resin (“OCR”), and a pressure sensitive adhesive (“PSA”).

FIG. 5 illustrates a cross-sectional view showing one G-C of the dam regions G-C, G-R, and G-L discussed in FIG. 3, and also showing the hole H-C next (adjacent) to the dam region G-C. The insulating layers mentioned above may extend onto the dam regions G-C, G-R, and G-L, and the insulating layers including an organic material may be patterned to constitute a portion of a dam pattern.

First to fifth dam patterns DMP1 to DMP5 may be disposed on the dam region G-C of the display panel DP. The first to fifth dam patterns DMP1 to DMP5 may be sequentially arranged in a direction from the display area DA toward the hole H-C. Each of the first to fifth dam patterns DMP1 to DMP5 may have a closed-line shape that surrounds the hole H-C.

Among the insulating layers mentioned above, the barrier layer BA and the insulating layers 10 to 50 each including an inorganic material may be disposed all over the display area DA and the dam region G-C.

Each of the first to fifth dam patterns DMP1 to DMP5 may include a first dielectric pattern 60-P, a second dielectric pattern 70-P, a first pattern SD1, and a second pattern SD2. The first pattern SD1 may be disposed on the first dielectric pattern 60-P. The second pattern SD2 may be disposed on the first pattern SD1. The first pattern SD1 and the second pattern SD2 may contact each other. The second dielectric pattern 70-P may be disposed on the first dielectric pattern 60-P, and may cover the second pattern SD2.

Each of the first and second dielectric patterns 60-P and 70-P may include an organic material. The first dielectric pattern 60-P may be a portion patterned from the sixth insulating layer 60 discussed in FIG. 4, and the second dielectric pattern 70-P may be a portion patterned from the seventh insulating layer 70 discussed in FIG. 4. Therefore, the first dielectric pattern 60-P may be disposed on the fifth insulating layer 50.

The first pattern SD1 and the first connection electrode CNE1, which is discussed in FIG. 4, may be formed in the same process and may include the same material as each other. The second pattern SD2 and the second connection electrode CNE2, which is discussed in FIG. 4, may be formed in the same process and may include the same material as each other. The first pattern SD1 and the second pattern SD2 may each include a first layer, a second layer, and a third layer that are sequentially stacked, where the first and third layers may include titanium, and where the second layer may include aluminum.

According to the disclosure, the second pattern SD2 included in each of the first to fifth dam patterns DMP1 to DMP5 may protrude from a lateral surface of the first dielectric pattern 60-P and a lateral surface of the second dielectric pattern 70-P, thereby defining a tip part TIP. At least two tip parts TIP included in neighboring ones of the first to fifth dam patterns DMP1 to DMP5 may face each other.

In the illustrated embodiment, the first to fifth dam patterns DMP1 to DMP5 may be covered with the first encapsulation inorganic layer 141. Thus, the first encapsulation inorganic layer 140 may also cover the second pattern SD2 that defines the tip part TIP in each of the first to fifth dam patterns DMP1 to DMP5.

The first dam pattern DMP1 may include two first patterns SD1 that are disposed on the first dielectric pattern 60-P and spaced apart from each other, and may also include the second patterns SD2 that are correspondingly in contact with the first patterns SD1. When viewed in cross-section, each of the second patterns SD2 may define two tip parts TIP that protrude from a lateral surface of the first dielectric pattern 60-P and a lateral surface of the second dielectric pattern 70-P.

In an embodiment, a sub-dam pattern DMP0 may further be included which is next (adjacent) to a boundary between the display area DA and the dam region G-C and is disposed on a distal end of the display area DA. The sub-dam pattern DMP0 may include the first pattern SD1 disposed on a distal end of the sixth insulating layer 60 and the second pattern SD2 in contact with the first pattern SD1. The second pattern SD2 may be covered with the seventh insulating layer 70. The second pattern SD2 of the sub-dam pattern DMP0 may define a tip part TIP that protrudes between the sixth insulating layer 60 and the seventh insulating layer 70.

In the illustrated embodiment, the tip part TIP of the sub-dam pattern DMP0 may face one tip part TIP of the first dam pattern DMP1.

The tip part TIP of the second dam pattern DMP2 may protrude in a left direction when viewed in cross-section, and may face a remaining (the other) tip part TIP of the first dam pattern DMP1. The tip part TIP of the third dam pattern DMP3 may protrude in a left direction when viewed in cross-section. Likewise the first dam pattern DMP1, each of the second patterns SD2 included in the fourth dam pattern DMP4 may define two tip parts TIP that protrude from a lateral surface of the first dielectric pattern 60-P and a lateral surface of the second dielectric pattern 70-P. The tip part TIP of the fifth dam pattern DMP5 may protrude in a direction toward the hole H-C.

In the illustrated embodiment, each of the first to fourth dam patterns DMP1 to DMP4 may further include a first dummy pattern G1 and a second dummy pattern G2. The first dummy pattern G1 may be disposed on the first insulating layer 10 and covered with the second insulating layer 20. The second dummy pattern G2 may overlap the first dummy pattern G1, may be disposed on the second insulating layer 20, and may be covered with the third insulating layer 30.

The first dummy pattern G1 may be formed in the same process for forming the gate GE1 of the first transistor T1 discussed in FIG. 4, and may include the same material as that of the gate GE1. The second dummy pattern G2 may be formed in the same process for forming the gate GE2 of the second transistor T2 discussed in FIG. 4, and may include the same material as that of the gate GE2. As each of the first to fourth dam patterns DMP1 to DMP4 includes the first dummy pattern G1 and the second dummy pattern G2, it may be possible to adjust heights of dam patterns.

The fifth dam pattern DMP5 (or an outermost dam pattern) may further include a dummy pattern B-P. The dummy pattern B-P may be disposed on the buffer layer BF discussed in FIG. 4. The first pattern SD1 of the fifth dam pattern DMP5 may be connected to the dummy pattern B-P through a contact hole that penetrates the first dielectric pattern 60-P and the first to fifth insulating layers 10 to 50 that overlap the dummy pattern B-P. The fifth dam pattern DMP5 may be a structure that prevents cracks, which occur in a process for forming the hole H-C, from propagating into the display area DA.

The step compensation layer YOC is disposed between the second encapsulation inorganic layer 143 and the planarization layer 150, and overlaps the first to fourth dam patterns DMP1 to DMP4, and may cover the step formed between the first to fourth dam patterns DMP1 to DMP4. The step compensation layer YOC may have a ring shape in a plan view and may include an organic material.

The planarization layer 150 is disposed over the display area DA and covers the step compensation layer YOC.

The hole H-C may be defined to penetrate the electronic device ED. The hole H-C may be defined to penetrate the display module DM and the window module WM. The hole H-C may receive the instrument cluster DB-C discussed above. The disclosure, however, is not limited thereto, and the hole H-C may be defined to penetrate only the display module DM, while the window module WM may be disposed on the instrument cluster DB-C.

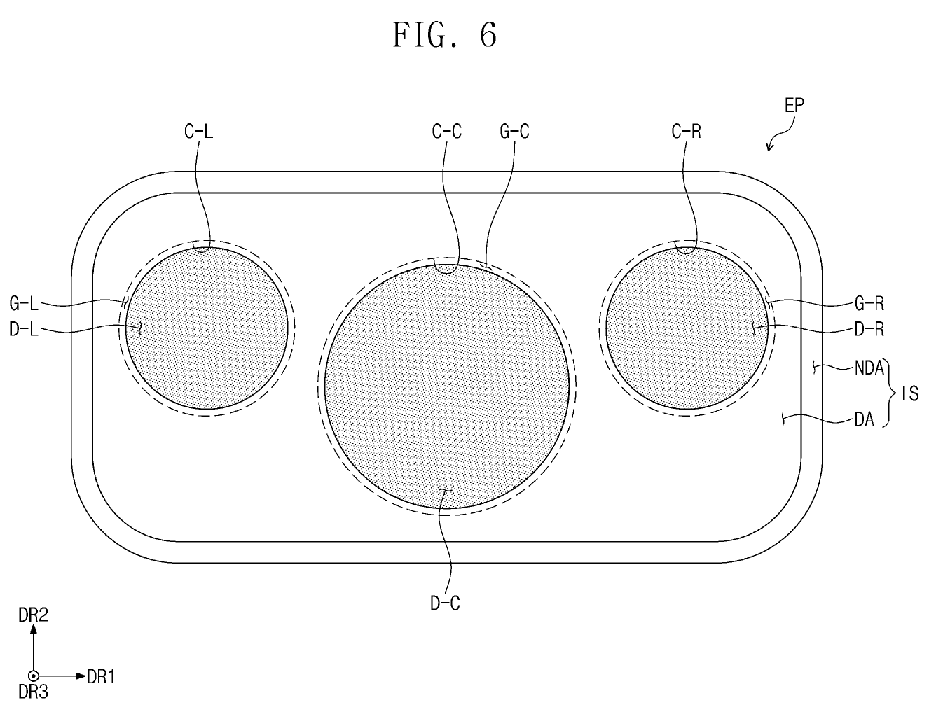

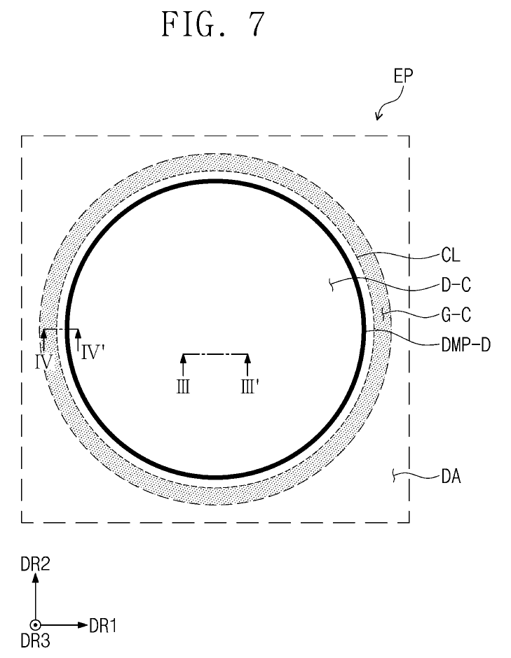

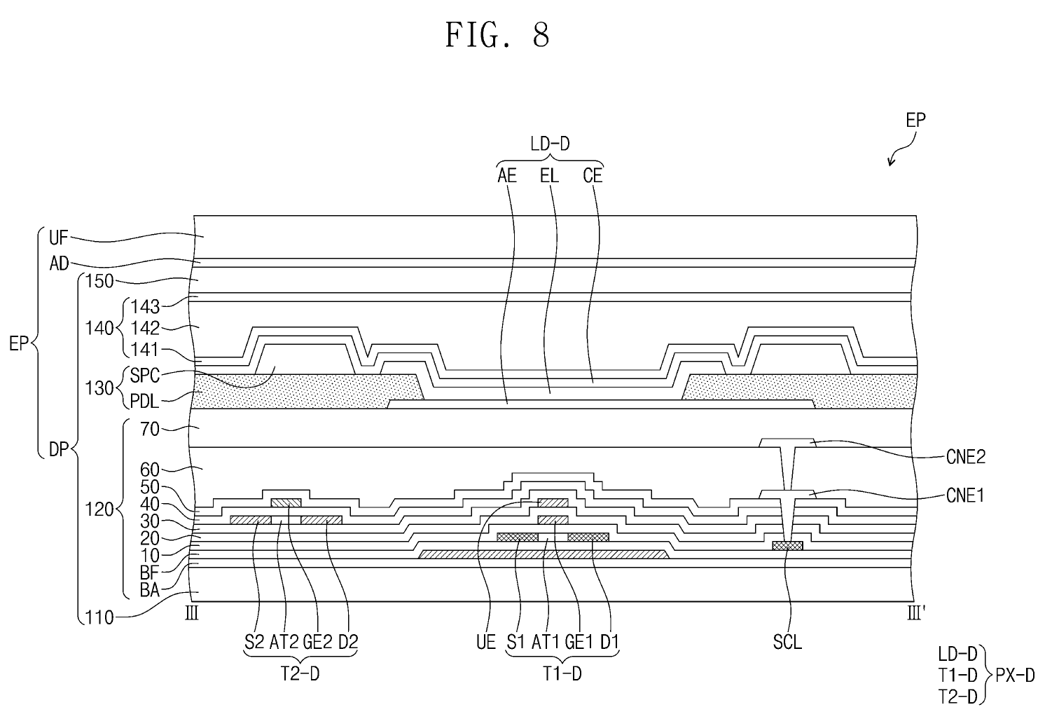

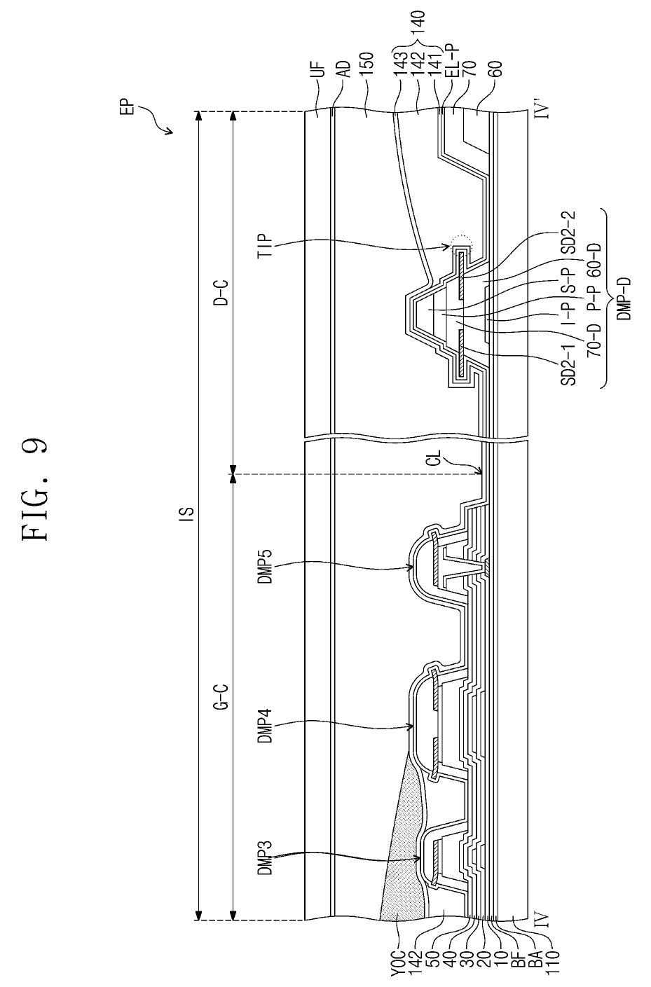

FIG. 6 illustrates a plan view showing an embodiment of an electronic panel. FIG. 7 illustrates an enlarged plan view partially showing an embodiment of an electronic panel. FIG. 8 illustrates a cross-sectional view taken along line III-III” of FIG. 7. FIG. 9 illustrates a cross-sectional view taken along line IV-IV’ of FIG. 7. The identical/similar reference numerals are allocated to the identical/similar components to those of FIGS. 2-5, and their duplicate descriptions will be omitted. FIGS. 6 and 7 illustrate plan views showing an embodiment of an electronic panel EP of the disclosure. FIG. 8 illustrates a cross-sectional view of the electronic panel EP.

The electronic panel EP may be referred to as a module before the defining of holes H-C, H-R, and H-L. The electronic panel EP may include a display panel DP, an adhesion layer AD, and an upper film UF. The display panel DP may correspond to the display panel DP discussed above.

The adhesion layer AD and the upper film UF may be components that are removed before a process in which the holes H-C, H-R, and H-L are defined. Therefore, an adhesive force of the adhesion layer AD to the upper film UF may be greater than that of the adhesion layer AD to the display panel DP.

In the electronic device ED, the holes H-C, H-R, and H-L may be defined through the following processes.

First, there may be included a process in which the display panel DP is formed. Then, a subsequent process may be included in which the upper film UF is coupled through the adhesion layer AD to the display panel DP. In a state where the electronic panel EP is formed, the electronic panel EP may be delivered, transported, or stored to define the holes H-C, H-R, and H-L.

Thereafter, a process may be included to remove the adhesion layer AD and the upper film UF from the display panel DP. A process may then be included to form the optical control member POL on the display panel DP. After that, a process may be included in which a laser is irradiated to define the holes H-C, H-R, and H-L. At this stage, the window module WM may be disposed on the optical control member POL.

An electronic panel EP will be discussed below with reference to FIGS. 6-8.

Referring to FIGS. 6 and 7, the electronic panel EP in an embodiment may include a display surface IS when viewed in plan. The display surface IS may include a display area DA and a non-display area NDA. Unlike the display area DA of the electronic device ED, none of the holes H-C, H-R, and H-L may be defined in the display area DA of the electronic panel EP. The display area DA of the electronic panel EP may include margin regions D-C, D-R, and D-L. The margin regions D-C, D-R, and D-L may be surrounded by their corresponding dam regions G-C, G-R, and G-L. The display area DA may surround the dam regions G-C, G-R, and G-L, and the dam regions G-C, G-R, and G-L may surround the margin regions D-C, D-R, and D-L.

Boundaries between the margin regions D-C, D-R, and D-L and the dam regions G-C, G-R, and G-L may be defined as cutting lines C-C, C-R, and C-L. In the process where the laser is irradiated to define the holes H-C, H-R, and H-L, the laser may be irradiated to the cutting lines C-C, C-R, and C-L. Therefore, the margin regions D-C, D-R, and D-L may be separated from the display area DA.

FIG. 7 depicts a planar shape of a dummy dam pattern DMP-D disposed on one margin region D-C. The dam region G-C may be a zone on which aforementioned dam patterns are disposed, and a boundary of the margin region D-C and the dam region G-C that surrounds the margin region D-C may be defined as a cutting line CL to which a laser is irradiated.

The dummy dam pattern DMP-D may be disposed along an edge of the margin region D-C. The dummy dam pattern DMP-D may be surrounded by the dam region G-C.

Referring to FIG. 8, dummy pixels PX-D may be disposed on the margin region D-C. A pixel may be defined to include the transistors T1 and T2 and the emission element LD connected thereto as discussed in FIG. 4.

Each of the dummy pixels PX-D may include dummy transistors T1-D and T2-D and a dummy emission element LD-D. The dummy transistors T1-D and T2-D may have their structures the same as those of the transistors T1 and T2 discussed in FIG. 4. Therefore, the dummy transistors T1-D and T2-D may be formed with the same process and the same material as those of the transistors T1 and T2.

The dummy emission element LD-D may have the same structure as that of the emission element LD discussed in FIG. 4. Thus, the dummy emission element LD-D and the emission element LD may include the same material formed in the same process.

However, the dummy pixels PX-D may not emit light. In an embodiment, the dummy transistors T1-D and T2-D may be disconnected to the dummy emission element LD-D. In an embodiment, a first electrode AE included in the dummy emission element LD-D may not be connected to the connection signal line SCL, for example. Thus, the dummy emission element LD-D may be in a floating state, and the dummy pixels PX-D may not operate. An arrangement of insulating layers disposed on the margin region D-C may be the same as that of insulating layers disposed on the display area DA, or may have a structure in which at least one insulating layer is omitted.

FIG. 9 illustrates a cross-sectional view showing the dam region G-C and the margin region D-C surrounded by the dam region G-C. The third, fourth, and fifth dam patterns DMP3, DMP4, and DMP5 disposed on the dam region G-C may correspond to the third, fourth, and fifth dam patterns DMP3, DMP4, and DMP5 discussed in FIG. 5.

Referring to FIG. 9, the dummy dam pattern DMP-D may be disposed on the margin region D-C. The dummy dam pattern DMP-D may be disposed along a boundary between the dam region G-C and the margin region D-C. The dummy dam pattern DMP-D may be covered with the first encapsulation inorganic layer 141.

The dummy dam pattern DMP-D may be disposed on the buffer layer BF. The dummy dam pattern DMP-D may include an inorganic pattern I-P, a first organic pattern 60-D, a second organic pattern 70-D, conductive patterns SD2-1 and SD2-2, and a third organic pattern P-P and S-P. The dummy dam pattern DMP-P may define a boundary of the encapsulation organic layer 142 disposed on the margin region D-C.

The inorganic pattern I-P may be disposed on the buffer layer BF. The inorganic pattern I-P may be formed in the same process for forming one of the first, second, third, fourth, and fifth insulating layers 10, 20, 30, 40, and 50. Therefore, the inorganic pattern I-P may include the same material as that of the one of the first, second, third, fourth, and fifth insulating layers 10, 20, 30, 40, and 50.

The first organic pattern 60-D may be disposed on the buffer layer BF and may cover the inorganic pattern I-P. The second organic pattern 70-D may be disposed on the first organic pattern 60-D. Each of the first and second organic patterns 60-D and 70-D may include an organic material. The first organic pattern 60-D may be a portion patterned from the sixth insulating layer 60 discussed in FIG. 4, and the second organic pattern 70-D may be a portion patterned from the seventh insulating layer 70 discussed in FIG. 4.

The conductive patterns SD2-1 and SD2-2 may include the same material as that of one of the first connection electrode CNE1 and the second connection electrode CNE2 that are discussed in FIG. 4. The conductive patterns SD2-1 and SD2-2 may each include a first layer, a second layer, and a third layer that are sequentially stacked, where the first and third layers may include titanium, and where the second layer may include aluminum.

The third organic pattern P-P and S-P may include a plurality of organic layers. A first layer P-P may be formed in the same process for forming the pixel definition layer PDL discussed in FIG. 4, and a second layer S-P disposed on the first layer P-P may be formed in the same process for forming the spacer SPC discussed in FIG. 4. The embodiment of the third organic pattern P-P and S-P, however, is not limited thereto, and at least one selected from the first layer P-P and the second layer S-P may be omitted.

According to the disclosure, the conductive patterns SD2-1 and SD2-2 included in the dummy dam pattern DMP-D may define tip parts TIP that protrude from a lateral surface of the first organic pattern 60-D and a lateral surface of the second organic pattern 70-D. In an embodiment, the dummy dam pattern DMP-D may include a first conductive pattern SD2-1 that protrudes toward the dam region G-C and a second conductive pattern SD2-2 that protrudes into the margin region D-C.

When a lifting phenomenon occurs on first and second encapsulation inorganic layers disposed on a margin region, a photoresist in a subsequent organic layer process may be introduced into a lifting portion such that insulating layers on a region next (adjacent) to the hole H-C may be delaminated in a process where the adhesion layer AD and the optical control member POL are separated as discussed in FIG. 8, thereby providing moisture/oxygen with a path through which the moisture/oxygen is introduced through the lifting portion into the display area DA.

According to the disclosure, as the conductive patterns SD2-1 and SD2-2 are included in the dummy dam pattern DMP-D disposed on an outermost portion of the margin region D-C, the first and second encapsulation inorganic layers 141 and 143 may be stably supported by the conductive patterns SD2-1 and SD2-2 when a chemical vapor deposition process is performed to form the first and second encapsulation inorganic layers 141 and 143.

Therefore, the lifting phenomenon of the first and second encapsulation inorganic layers 141 and 143 may be avoided to prevent cracks from being generated in the first and second encapsulation inorganic layers 141 and 143 and a photoresist in a subsequent organic layer process from being introduced below cracks generated in the first and second encapsulation inorganic layers 141 and 143.

This may prevent a problem of delamination of insulating layers formed on the display panel DP in a process where the adhesion layer AD and the optical control member POL are separated from the display panel DP as discussed in FIG. 8 before a process of defining the hole H-C. Thus, the process of defining the hole H-C may improve in reliability.

In the illustrated embodiment, an emission pattern EL-P may be disposed on the margin region D-C. The emission pattern EL-P may cover the dummy dam pattern DMP-D. The emission pattern EL-P may be formed in the same process for forming the emission layer EL of the dummy pixel PX-D discussed in FIG. 8. As a mask is not provided on the margin region D-C when the emission layer EL is formed, the emission pattern EL-P may be formed to cover the dummy dam pattern DMP-D.

The first, second, third, fourth, and fifth insulating layers 10, 20, 30, 40, and 50 discussed in FIG. 4 may be disposed only onto the fifth dam pattern DMP5 on the dam region G-C, and may not be disposed on the margin region D-C. The barrier layer BA and the buffer layer BF may extend from the display area DA through the dam region G-C to the margin region D-C.

The first and second encapsulation inorganic layers 141 and 143 discussed in FIG. 4 may extend from the display area DA through the dam region G-C to the margin region D-C. The first and second encapsulation inorganic layers 141 and 143 may contact each other from the fourth dam pattern DMP4 to one side of the dummy dam pattern DMP-D of the margin region D-C.

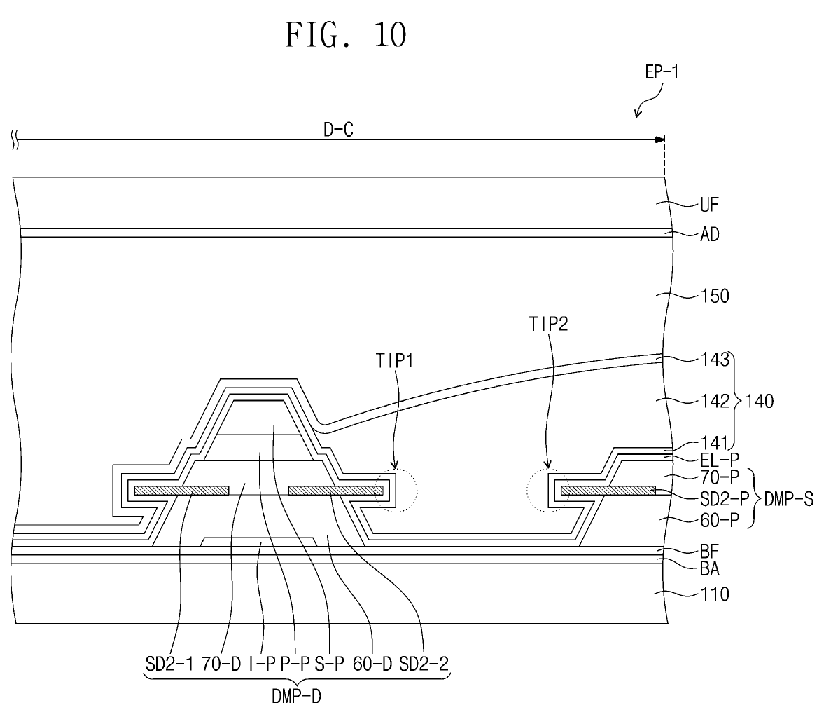

FIG. 10 illustrates a cross-sectional view showing an embodiment of a margin region of an electronic panel. The identical/similar reference numerals are allocated to the identical/similar components to those of FIG. 9, and their duplicate descriptions will be omitted.

Referring to FIG. 10, an electronic panel EP-1 in an embodiment may be configured such that the margin region D-C may include a dummy dam pattern DMP-D and a protruding dam pattern DMP-S. The dummy dam pattern DMP-D may correspond to that discussed above.

The protruding dam pattern DMP-S may include a protruding pattern SD2-P, a second protruding organic pattern 70-P, and a first protruding organic pattern 60-P which are closer (more adjacent) to the dummy dam pattern DMP-D than other dam patterns are to the dummy dam pattern DMP-D in the margin region D-C.

The first protruding organic pattern 60-P may be defined as a distal end of the sixth insulating layer 60 that extends from a region on which the dummy pixel PX-D is disposed as discussed in FIG. 8 and faces the dummy dam pattern DMP-D. The second protruding organic pattern 70-P may be defined as a distal end of the seventh insulating layer 70 that extends from a region on which the dummy pixel PX-D is disposed as discussed in FIG. 8 and faces the dummy dam pattern DMP-D.

The protruding pattern SD2-P may protrude between a lateral surface of the first protruding organic pattern 60-P and a lateral surface of the second protruding organic pattern 70-P.

The conductive patterns SD2-1 and SD2-2 of the dummy dam pattern DMP-D may define a first tip part TIP1, and the protruding pattern SD2-P of the protruding dam pattern DMP-S may define a second tip part TIP2. The first tip part TIP1 and the second tip part TIP2 may face each other.

An emission pattern EL-P may be disposed on the margin region D-C. The emission pattern EL-P may cover the protruding dam pattern DMP-S and the dummy dam pattern DMP-D. Therefore, the emission pattern EL-P may cover the conductive patterns SD2-1 and SD2-2 and the protruding pattern SD2-P that define the tip parts TIP1 and TIP2 on the margin region D-C.

The first encapsulation inorganic layer 141 may be disposed on the emission pattern EL-P. As the electronic panel EP-1 in the illustrated embodiment includes the tip parts TIP1 and TIP2 that face each other on the margin region D-C, the first and second encapsulation inorganic layers 141 and 143 may be stably supported by the conductive patterns SD2-1 and SD2-2 and the protruding pattern SD2-P.

Therefore, a lifting phenomenon of the first and second encapsulation inorganic layers 141 and 143 may be avoided to prevent cracks from being generated in the first and second encapsulation inorganic layers 141 and 143 and a photoresist in a subsequent organic layer process from being introduced below cracks generated in the first and second encapsulation inorganic layers 141 and 143.

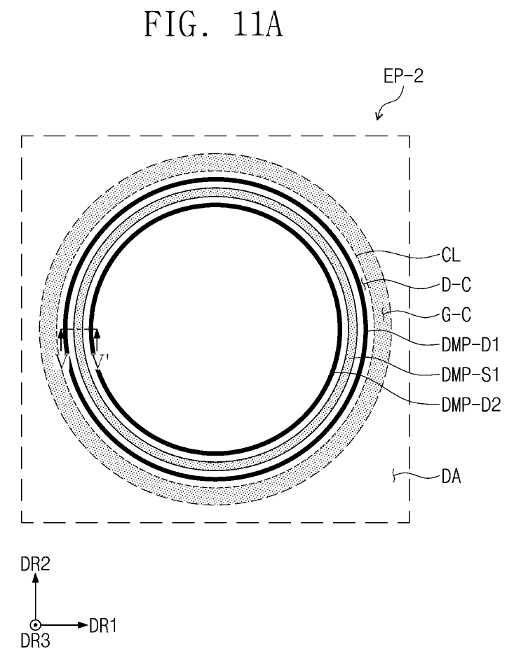

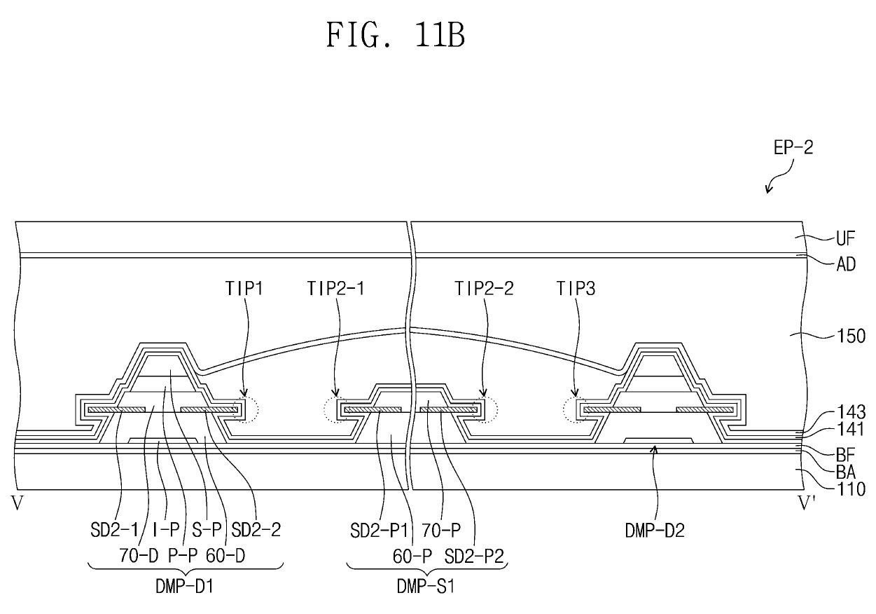

FIG. 11A illustrates a plan view showing an embodiment of an electronic panel. FIG. 11B illustrates a cross-sectional view taken along line V-V’ of FIG. 11A. The identical/similar reference numerals are allocated to the identical/similar components to those of FIGS. 3-10, and their duplicate explanations will be omitted.

Referring to FIGS. 11A and 11B, an electronic panel EP-2 in an embodiment may be configured such that the margin region D-C may include first and second dummy dam patterns DMP-D1 and DMP-D2 and a protruding dam pattern DMP-S1. In the illustrated embodiment, the protruding dam pattern DMP-S1 may be disposed between the first and second dummy dam patterns DMP-D1 and DMP-D2.

Each of the first and second dummy dam patterns DMP-D1 and DMP-D2 may correspond to the dummy dam pattern DMP-D discussed in FIG. 9. Therefore, each of the first and second dummy dam patterns DMP-D1 and DMP-D2 may include the inorganic pattern I-P, the first organic pattern 60-D, the second organic pattern 70-D, the conductive patterns SD2-1 and SD2-2, and the third organic pattern P-P and S-P.

The protruding dam pattern DMP-S1 may correspond to the protruding dam pattern DMP-S discussed in FIG. 10. The protruding dam pattern DMP-S1 may include a first protruding organic pattern 60-P whose one side is closer (more adjacent) to the first dummy dam pattern DMP-D1 than other sides of the first protruding organic pattern 60-P are to the first dummy dam pattern DMP-D1 and whose another side is closer (more adjacent) to the second dummy dam pattern DMP-D2 than other sides of the first protruding organic pattern 60-P are to the second dummy dam pattern DMP-D2, a second protruding organic pattern 70-P whose one side is closer (more adjacent) to the first dummy dam pattern DMP-D1 than other sides of the second protruding organic pattern 70-P are to the first dummy dam pattern DMP-D1 and whose another side is closer (more adjacent) to the second dummy dam pattern DMP-D2 than other sides of the second protruding organic pattern 70-P are to the second dummy dam pattern DMP-D2, a first protruding pattern SD2-P1 that protrudes in a direction toward the first dummy dam pattern DMP-D1, and a second protruding pattern SD2-P2 that protrudes in a direction toward the second dummy dam pattern DMP-D2.

Therefore, the protruding dam pattern DMP-S1 may have a 2-1^{st} tip part TIP2-1 that faces a first tip part TIP1 of the first dummy dam pattern DMP-D1 and a 2-2^{nd} tip part TIP2-2 that faces a third tip part TIP3 of the second dummy dam pattern DMP-D2.

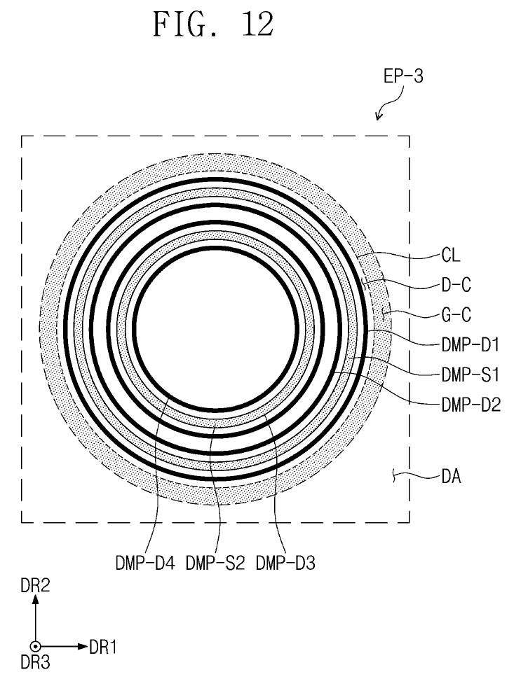

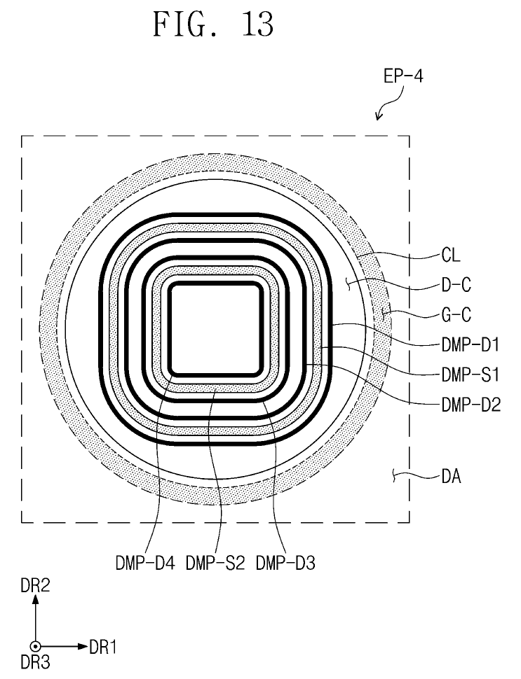

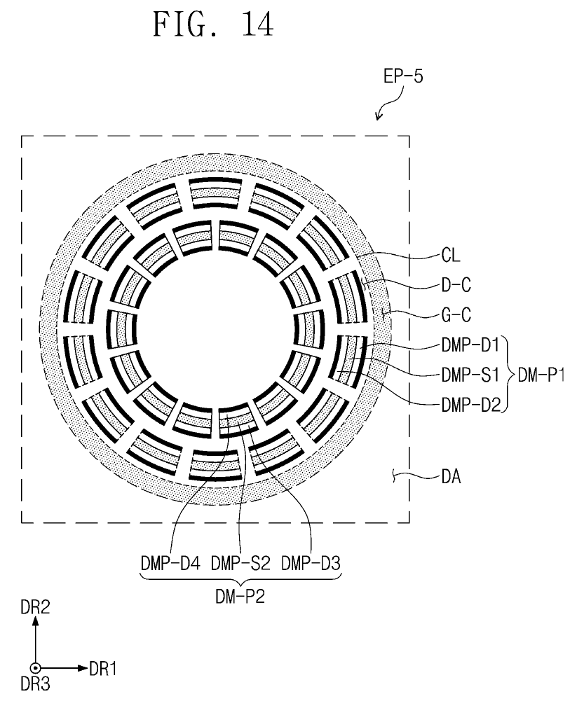

FIG. 12 illustrates a plan view showing an embodiment of an electronic panel. FIG. 13 illustrates a plan view showing an embodiment of an electronic panel. FIG. 14 illustrates a plan view showing an embodiment of an electronic panel. The identical/similar reference numerals are allocated to the identical/similar components to those of FIGS. 11A and 11B, and their duplicate explanations will be omitted.

Referring to FIG. 12, an electronic panel EP-3 in an embodiment may be configured such that the margin region D-C may include first to fourth dummy dam patterns DMP-D1 to DMP-D4 and first and second protruding dam patterns DMP-S1 and DMP-S2. The first to fourth dummy dam patterns DMP-D1 to DMP-D4 may have the same structure as that of the first and second dummy dam patterns DMP-D1 and DMP-D2 discussed in FIGS. 11A and 11B, and the first and second protruding dam patterns DMP-S1 and DMP-S2 may have the same structure as that of the protruding dam pattern DMP-S1 discussed in FIGS. 11A and 11B.

In the illustrated embodiment, the first dummy dam pattern DMP-D1 may be disposed closer (more adjacent) to the cutting line CL than other dummy dam patterns. The second dummy dam pattern DMP-D2 may be surrounded by the first dummy dam pattern DMP-D1. The first protruding dam pattern DMP-S1 may be disposed between the first dummy dam pattern DMP-D1 and the second dummy dam pattern DMP-D2.

The first dummy dam pattern DMP-D1 and one side of the first protruding dam pattern DMP-S1 may define tip parts that face each other, and the second dummy dam pattern DMP-D2 and another side of the first protruding dam pattern DMP-S1 may define tip parts that face each other.

The third dummy dam pattern DMP-D3 may be surrounded by the second dummy dam pattern DMP-D2. The fourth dummy dam pattern DMP-D4 may be surrounded by the third dummy dam pattern DMP-D3. The second protruding dam pattern DMP-S2 may be disposed between the third dummy dam pattern DMP-D3 and the fourth dummy dam pattern DMP-D4.

The third dummy dam pattern DMP-D3 and one side of the second protruding dam pattern DMP-S2 may define tip parts that face each other, and the fourth dummy dam pattern DMP-D4 and another side of the second protruding dam pattern DMP-S2 may define tip parts that face each other.

In the illustrated embodiment, the first to fourth dummy dam patterns DMP-D1 to DMP-D4 and the first and second protruding dam patterns DMP-S1 and DMP-S2 may each have a circular shape when viewed in plan. The planar shape, however, is not limited thereto, and an oval shape or a polygonal shape may be possible.

In addition, planar shapes of the first to fourth dummy dam patterns DMP-D1 to DMP-D4 and the first and second protruding dam patterns DMP-S1 and DMP-S2 may correspond to those of dam patterns disposed on the dam region (refer to G-C in FIG. 9).

Referring to FIG. 13, an electronic panel EP-4 in an embodiment may be configured such that the margin region D-C may include first to fourth dummy dam patterns DMP-D1 to DMP-D4 and first and second protruding dam patterns DMP-S1 and DMP-S2. The first to fourth dummy dam patterns DMP-D1 to DMP-D4 may have the same structure as that of the first to fourth dummy dam patterns DMP-D1 to DMP-D4 discussed in FIG. 12, and the first and second protruding dam patterns DMP-S1 and DMP-S2 may have the same structure as that of the first and second protruding dam patterns DMP-S1 and DMP-S2 discussed in FIG. 12.

In the illustrated embodiment, planar shapes of the first to fourth dummy dam patterns DMP-D1 to DMP-D4 and the first and second protruding dam patterns DMP-S1 and DMP-S2 may be different from those of dam patterns disposed on the dam region (refer to G-C in FIG. 9).

In an embodiment, the first to fourth dummy dam patterns DMP-D1 to DMP-D4 and the first and second protruding dam patterns DMP-S1 and DMP-S2 may each have a tetragonal shape whose corners are rounded when viewed in plan. The dam region (refer to G-C in FIG. 9) may include dam patterns each having a circular shape.

Referring to FIG. 14, an electronic panel EP-5 in an embodiment may be configured such that the margin region D-C may include first dam patterns DM-P1 and second dam patterns DM-P2 spaced apart from the first dam patterns DM-P1.

Each of the first dam patterns DM-P1 may include the first and second dummy dam patterns discussed in FIG. 12, and may also include the first protruding dam pattern DMP-S1, which is discussed in FIG. 12, between the first and second dummy dam patterns DMP-D1 and DMP-D2. The base layer 110, the barrier layer BA, the buffer layer BF, the first encapsulation inorganic layer 141, and the second encapsulation inorganic layer 143, which are discussed in FIG. 9, may contact each other and stacked between neighboring first dam patterns DM-P1. When viewed in plan, the first dam patterns DM-P1 may be spaced apart from each other to constitute a circular band shape.

Each of the second dam patterns DM-P2 may include the third and fourth dummy dam patterns DMP-D3 and DMP-D4 discussed in FIG. 12, and may also include the second protruding dam pattern DMP-S2, which is discussed in FIG. 12, between the third and fourth dummy dam patterns DMP-D3 and DMP-D4. The base layer 110, the barrier layer BA, the buffer layer BF, the first encapsulation inorganic layer 141, and the second encapsulation inorganic layer 143, which are discussed in FIG. 9, may contact each other and stacked between neighboring second dam patterns DM-P2. When viewed in plan, the second dam patterns DM-P2 may be spaced apart from each other to constitute a circular band shape, and may be surrounded by the first dam patterns DM-P1.

In some embodiments of the disclosure, as a tip part is included in a dam pattern disposed on a margin region where a hole is defined, it may be possible to prevent delamination of insulating layers formed on a display panel in a process where an adhesion layer and an optical control member are separated from the display panel before the hole is defined. Consequently, an electronic device in which the hole is defined may improve in reliability.

Although the embodiments have been described with reference to a number of illustrative examples thereof, it will be understood by those of ordinary skill in the art that various changes in form and details may be made without departing from the spirit and scope of the disclosure as set forth in the following claims.

Thus, the technical scope of the inventive concepts is not limited by the embodiments and examples described above, but by the following claims.

What is claimed is:

1. An electronic panel comprising:
a display panel including a display area including a margin region and a dam region which surrounds the margin region, the display panel comprising:
a base layer;
a plurality of insulating layers on the base layer;
a plurality of pixels on the base layer which overlaps the display area;
an encapsulation layer which covers the plurality of pixels, the encapsulation layer including:
a first encapsulation inorganic layer;
a second encapsulation inorganic layer; and
an encapsulation organic layer between the first encapsulation inorganic layer and the second encapsulation inorganic layer;
a plurality of dam patterns on the dam region; and
a dummy dam pattern along a boundary of the margin region, the dummy dam pattern comprising:
an inorganic pattern;
a first organic pattern on the inorganic pattern;
a second organic pattern on the first organic pattern;
a conductive pattern between the first and second organic patterns, the conductive pattern protruding from the first and second organic patterns; and
a third organic pattern on the second organic pattern; and
an upper film on the display panel.

2. The electronic panel of claim 1, wherein, within the margin region, the dummy dam pattern defines a boundary of the encapsulation organic layer,
wherein the encapsulation organic layer is absent between the dummy dam pattern and an outermost dam pattern of the plurality of dam patterns, the outermost dam pattern being closest to the margin region among the plurality of dam patterns.

3. The electronic panel of claim 1, wherein
each of the plurality of pixels comprises:
a first electrode;
a second electrode on the first electrode; and
an emission layer between the first electrode and the second electrode, and
the electronic panel further comprises an emission pattern layer on the margin region, the emission pattern layer covering the dummy dam pattern.

4. The electronic panel of claim 3, wherein the emission pattern layer comprises a material the same as a material of the emission layer.

5. The electronic panel of claim 3, wherein the first encapsulation inorganic layer covers the plurality of dam patterns on the dam region and the emission pattern layer on the margin region.

6. The electronic panel of claim 1, wherein the plurality of insulating layers comprises:
a plurality of inorganic insulating layers each including an inorganic material;
a first organic insulating layer on the plurality of inorganic insulating layers; and
a second organic insulating layer on the first organic insulating layer.

7. The electronic panel of claim 6, wherein none of the first organic insulating layer and the second organic insulating layer is disposed between the dummy dam pattern and a boundary between the dam region and the margin region.

8. The electronic panel of claim 7, wherein the first encapsulation inorganic layer and the second encapsulation inorganic layer contact each other from one of the plurality of dam patterns to the dummy dam pattern.

9. The electronic panel of claim 6, wherein each of the plurality of dam patterns comprises:
a first dielectric pattern;
a first pattern on the first dielectric pattern;
a second pattern on the first pattern; and
a second dielectric pattern on the first dielectric pattern,
wherein the second pattern protrudes between the first and second dielectric patterns.

10. The electronic panel of claim 9, wherein
the first organic pattern and the first dielectric pattern comprise a material the same as a material of the first organic insulating layer, and
the second organic pattern and the second dielectric pattern comprise a material the same as a material of the second organic insulating layer.

11. The electronic panel of claim 10, wherein the display panel further comprises:
a pixel definition layer on the second organic insulating layer, the pixel definition layer including a plurality of openings each of which exposes at least a portion of a first electrode included in each of the plurality of pixels; and
a spacer on the pixel definition layer.

12. The electronic panel of claim 11, wherein the third organic pattern comprises a material the same as a material of at least one selected from the pixel definition layer and the spacer.

13. The electronic panel of claim 1, wherein the plurality of pixels comprises a transistor and an emission element connected to the transistor.

14. The electronic panel of claim 13, further comprising a plurality of dummy pixels which overlap the margin region and are surrounded by the dummy dam pattern.

15. The electronic panel of claim 14, wherein each of the plurality of dummy pixels comprises:
a dummy transistor which has a structure the same as a structure of the transistor; and
a dummy emission element which has a structure the same as a structure of the emission element,
wherein the dummy transistor is disconnected to the dummy emission element.

16. The electronic panel of claim 15, further comprising a protruding pattern between organic layers of the plurality of insulating layers on the margin region, the organic layers facing the dummy dam pattern,
wherein the protruding pattern protrudes in a direction toward the dummy dam pattern.

17. The electronic panel of claim 1, further comprising a step compensation layer on the second encapsulation inorganic layer, the step compensation layer overlapping at least one of the plurality of dam patterns and including an organic material,
wherein the step compensation layer has a ring shape.

18. The electronic panel of claim 17, further comprising:
a planarization layer on an entirety of the display area, the planarization layer covering the step compensation layer; and
an adhesion layer between the planarization layer and the upper film.

19. The electronic panel of claim 18, wherein the adhesion layer and the upper film are separable from the planarization layer.

20. The electronic panel of claim 1, wherein, when viewed in plan, an arrangement of the plurality of dam patterns is different from an arrangement of the dummy dam pattern.
